(19) United States
(12) Patent Application Publication
(10) Pub. No.: US 2014/0356993 A1
(43) Pub. Date: Dec. 4, 2014

(54) LIGHT-EMITTING DEVICE AND METHOD FOR MANUFACTURING THE SAME

(71) Applicant: EPISTAR CORPORATION, Hsinchu (TW)

(72) Inventor: Chih-Hao WEI, Hsinchu (TW)

(73) Assignee: EPISTAR CORPORATION, Hsinchu (TW)

(21) Appl. No.: 14/294,832

(22) Filed: Jun. 3, 2014

(30) Foreign Application Priority Data
Jun. 3, 2013 (TW) 102119720

(51) Int. Cl. H01L 23/00; H01L 31/18; H01L 27/15

(52) U.S. Cl. CPC H01L 24/97; H01L 27/15; H01L 31/1892
USPC 438/28

(57) ABSTRACT

A method for manufacturing a light-emitting device, comprises the steps of: providing a carrier; performing a coating step comprises coating a film on the carrier; performing a baking step comprises baking the film at a first temperature; and forming a thick film by repeating the coating step and the baking step a predetermined number of times.

### TECHNICAL FIELD

The disclosure relates to a method for manufacturing light-emitting device, and more particularly to a method for manufacturing a light-emitting device comprising a thick film.

### REFERENCE TO RELATED APPLICATION

This application claims the right of priority based on TW application Serial No. 102119720, filed on Jun. 3, 2013, and the content of which is hereby incorporated by reference in its entirety.

### DESCRIPTION OF BACKGROUND ART

The principle of light emission of a light-emitting diode (LED) is different from that of an incandescent light. Besides, the junction temperature of a light-emitting diode (LED) is much lower than the filament temperature of an incandescent light, and therefore an LED is a cold light source. Furthermore, the Light-emitting diodes have advantages such as high durability, longer lifetime, lower power consumption and small size. As a result, the lighting market has high expectation of the light-emitting diodes becoming a new generation of lighting sources to gradually replace the conventional light sources, while the light-emitting diodes are applied to various fields such as traffic lights, back light modules, street lighting, and medical equipment.

FIG. 1a illustrates a conventional light-emitting device. As shown in FIG. 1a, the conventional light-emitting device 100 comprises a transparent substrate 11, a semiconductor stack 12 on the transparent substrate 11, and an electrode 14 on the semiconductor stack 12, wherein the semiconductor stack 12 comprises a first conductive semiconductor layer 120, an active layer 122 and a second conductive semiconductor layer 124 in sequence in a direction from the electrode 14 to the transparent substrate 11.

Besides, the light-emitting device 100 mentioned above is able to further combine with other elements to form a light-emitting apparatus as shown in FIG. 1b. FIG. 1b illustrates a conventional light-emitting apparatus 200, comprising a submount 21 comprising a circuit 150, a solder 22 on the submount 21, by which the above light-emitting device 100 can be fixed on the submount 21, and by which the substrate 11 of the above light-emitting device 100 is electrically connected to the circuit 150 on the submount 21; and an electrical connection structure 24 for electrically connecting a pad 14 of the light-emitting device 100 and the circuit 150 on the submount 21; wherein the submount 21 can be a lead frame or a large mounting substrate for facilitating the design of the electrical circuit of the light-emitting apparatus 200 and increasing the heat dissipation efficiency.

### SUMMARY OF THE DISCLOSURE

A method for manufacturing a light-emitting device, comprises the steps of: providing a carrier; performing a coating step comprises coating a film on the carrier; performing a baking step comprises baking the film at a first temperature; and forming a thick film by repeating the coating step and the baking step a predetermined number of times.

### BRIEF DESCRIPTION OF THE DRAWINGS

FIG. 1a illustrates a conventional light-emitting device;

FIG. 1b illustrates a conventional light-emitting apparatus;

FIGS. 2a through 2g illustrate a light-emitting device during a manufacturing process in accordance with the first embodiment of the present application;

FIGS. 3a through 3j illustrate a light-emitting device during a manufacturing process in accordance with the second embodiment of the present application; and

FIG. 4 is an exploded view of a light bulb in accordance with the third embodiment of the present application.

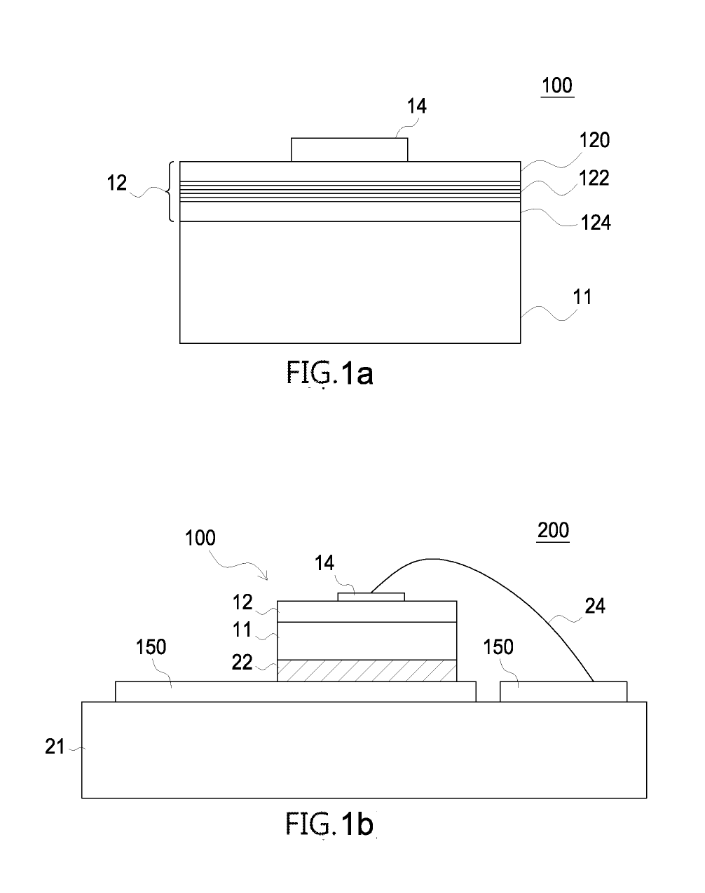

### DETAILED DESCRIPTION OF PREFERRED EMBODIMENTS

Exemplary embodiments of the present application will be described in detail with reference to the accompanying drawings hereafter. The following embodiments are given by way of illustration to help those skilled in the art fully understand the spirit of the present application. Hence, it should be noted that the present application is not limited to the embodiments herein and can be realized by various forms. Further, the drawings are not precise scale and components may be exaggerated in view of width, height, length, etc. Herein, the similar or identical reference numerals will denote the similar or identical components throughout the drawings.

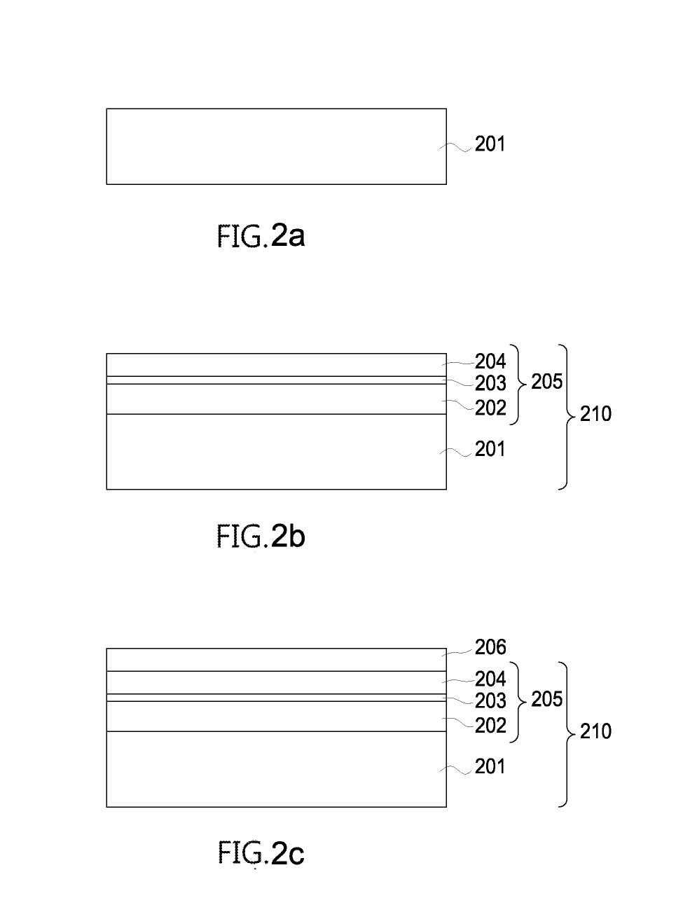

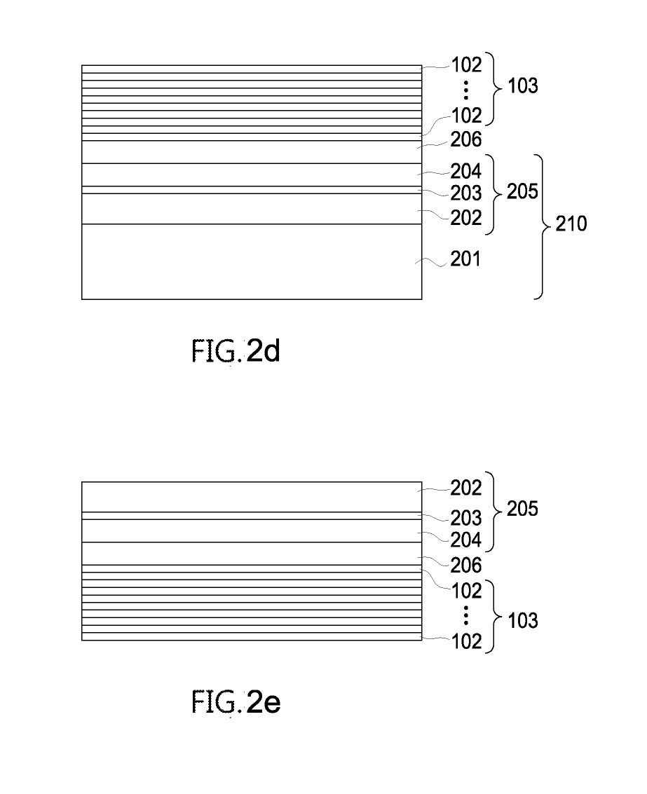

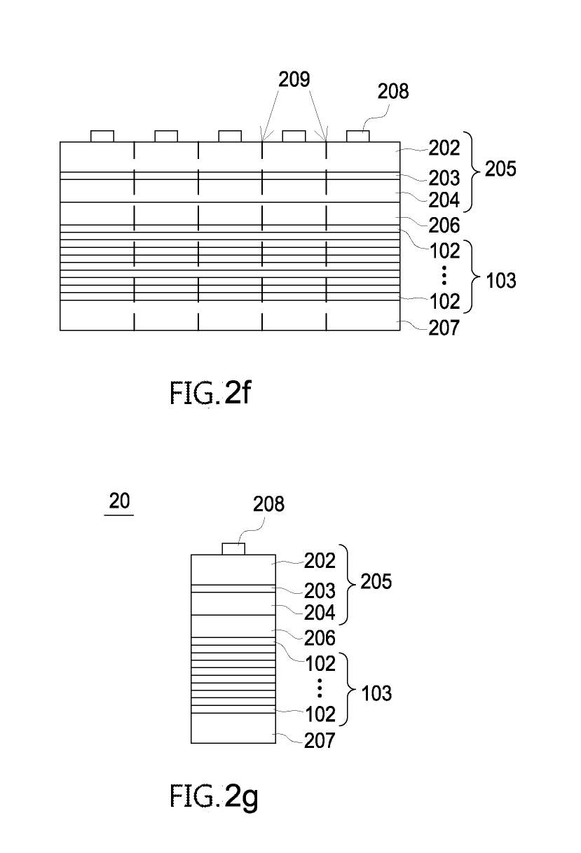

FIGS. 2a through 2g illustrate a light-emitting device during a manufacturing process in accordance with the first embodiment of the present application. The method for manufacturing the light-emitting device comprises the steps of: providing a first substrate 201, as shown in FIG. 2a; forming a light-emitting diode structure 205 on the first substrate 201 by metal-organic chemical vapor deposition (MOCVD), wherein the light-emitting diode structure 205 comprises a first conductive type semiconductor layer 202, an active layer 203 and a second conductive type semiconductor layer 204 in sequence in a direction away from the first substrate 201, as shown in FIG. 2b. In the present embodiment, a carrier 210 includes the first substrate 201 and the light-emitting diode structure 205.

Next, referring to FIG. 2c, a dense layer 206 is formed on the light-emitting diode structure 205. A method of forming the dense layer 206 comprises physical vapor deposition or chemical vapor deposition. A material of the dense layer 206 comprises metal oxide, metal nitride, or GaP, wherein metal oxide comprises zinc oxide, indium oxide, tin oxide, indium tin oxide, indium zinc oxide, fluorine doped tin oxide, zinc aluminum oxide or gallium zinc oxide, wherein metal nitride comprises gallium nitride or aluminum nitride.

A film 102 is then formed on the dense layer 206. The film 102 comprises conductive nano-powders. In the present embodiment, the conductive nano-powders are formed by physical method or chemical method with targets made of indium tin oxide (ITO) or ZnO, wherein the physical method comprises rolling milling, vapor condensation or comminution, and wherein the chemical method comprises vapor deposition, precipitation, hydrothermal synthesis, sol-gel method or micro-emulsion. The film 102 further comprises a binder (not shown) for binding the conductive nano-powders together. The film 102 can be formed on the dense layer 206 by coating, wherein a method of coating comprises spin-coating or blade coating. In the present embodiment, a thickness of the film 102 ranges from 10 μm to 30 μm. Furthermore, the dense layer 206 is advantageous for enhancing adhesion between the film 102 and the light-emitting diode structure 205.

A step of baking the film 102 is then performed at a first temperature. After that, the step of forming the film 102 by coating and the step of baking the film 102 are repeated a predetermined number of times so as to form a thick film 103, wherein the predetermined number of times is at least 10 times or at least 20 times, as shown in FIG. 2d. Next, a pressure is applied to the thick film 103 at a second temperature, wherein the second temperature is higher than the first temperature. A thickness of the thick film 103 ranges from 100 μm to 600 μm, a transmittance of the thick film 103 ranges from 60% to 90% in the wavelength range of the light emitted from the light-emitting diode structure 205, and a resistivity of the thick film 103 ranges from 10⁻² to 10⁻⁴ Ω/cm.

A material of the nano-powders may be the same or different from a material of the dense layer 206, wherein the material of the nano-powders comprises metal oxide, metal nitride, or GaP, wherein metal oxide comprises zinc oxide, indium oxide, tin oxide, indium tin oxide, indium zinc oxide, fluorine doped tin oxide, zinc aluminum oxide or gallium zinc oxide, wherein metal nitride comprises gallium nitride or aluminum nitride. Besides, a material of the binder comprises low-temperature glass or nano silicon dioxide, wherein the low-temperature glass herein is defined as a material having a glass transition temperature ranging from 75° C. to 150° C., and the nano silicon dioxide herein is defined as silicon dioxide grains or silicon dioxide powders having a size smaller than 100 nm.

The first substrate 201 is then removed to expose the first conductive type semiconductor layer 202 of the light-emitting diode structure 205, as shown in FIG. 2e, wherein the method for removing the first substrate 201 comprises wet etching or dry etching. Referring to FIG. 2f, a conductive reflective layer 207 is formed on a surface of the thick film 103 away from the dense layer 206, wherein the conductive reflective layer 207 is composed of metal and functions as a reflective layer and an electrode simultaneously. Referring to FIGS. 2f to 2g, an electrode 208 is formed on the first conductive type semiconductor layer 202 and a light-emitting device 20 is formed after dicing along the scribing lines 209.

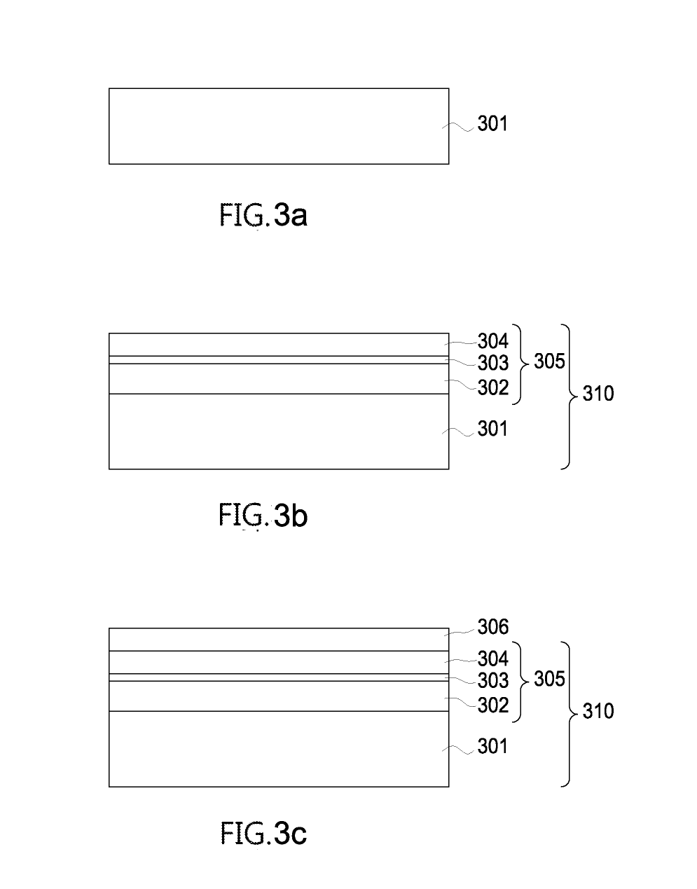

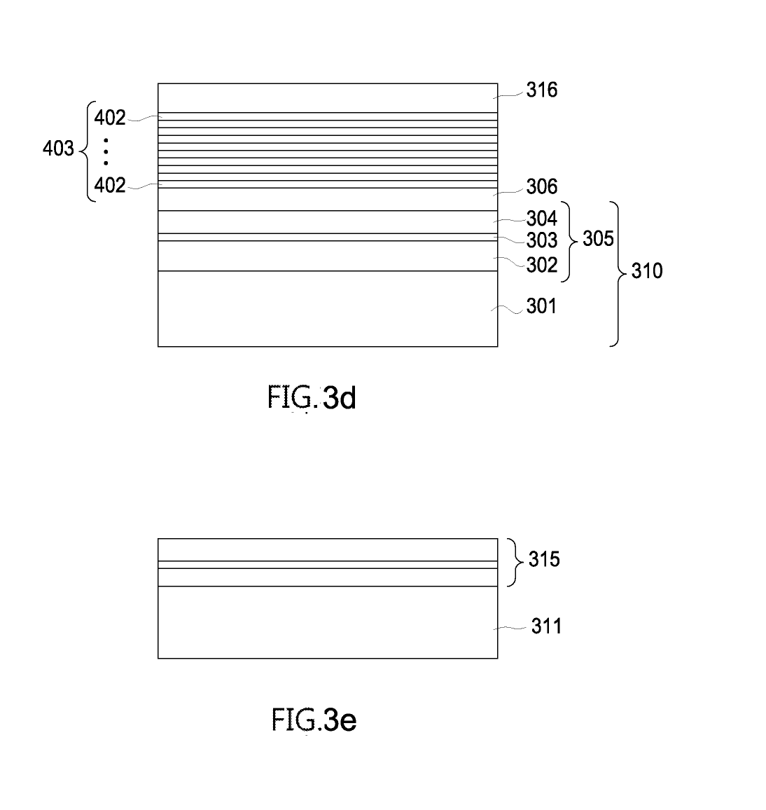

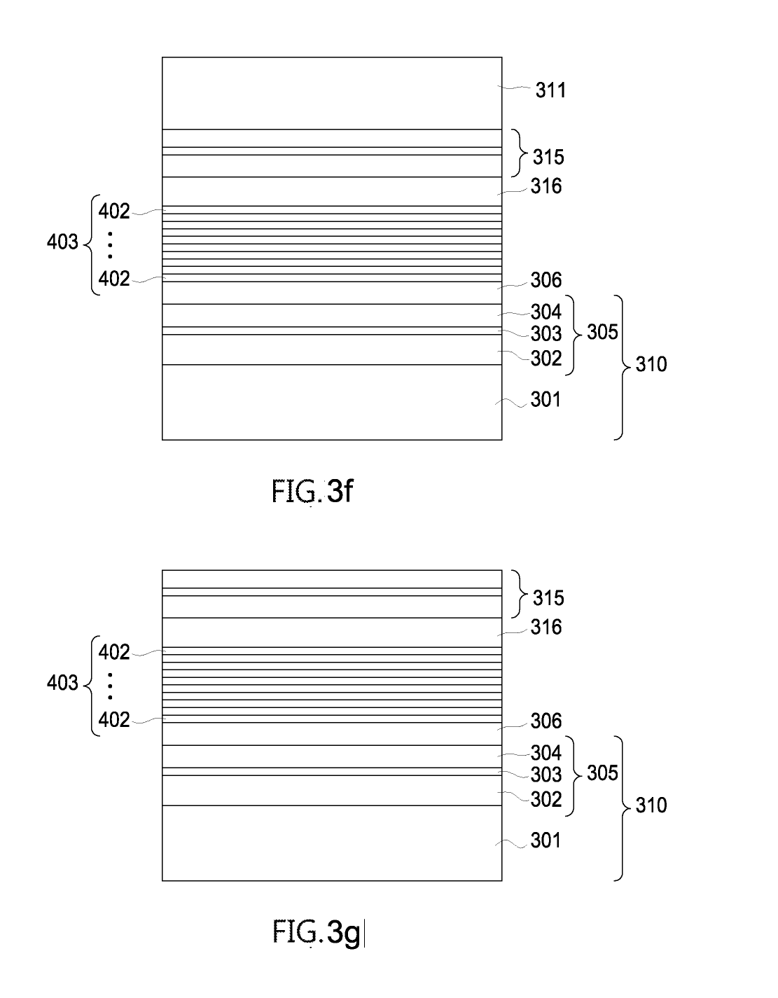

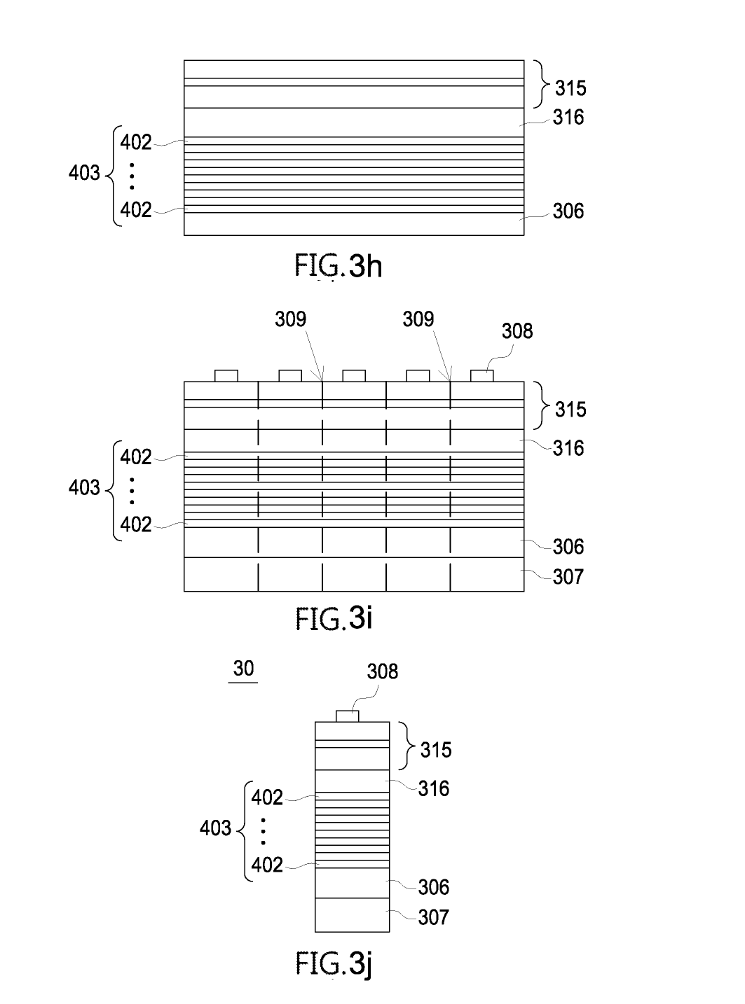

FIGS. 3a through 3j illustrate a light-emitting device during a manufacturing process in accordance with the second embodiment of the present application. The method for manufacturing the light-emitting device comprises the steps of: providing a first substrate 301, as shown in FIG. 3a; forming a light-emitting diode structure 305 on the first substrate 301 by metal-organic chemical vapor deposition (MOCVD), wherein the light-emitting diode structure 305 comprises a first conductive type semiconductor layer 302, an active layer 303 and a second conductive type semiconductor layer 304 in sequence in a direction away from the first substrate 301, as shown in FIG. 3b. In the present embodiment, a carrier 310 includes the first substrate 301 and the light-emitting diode structure 305.

Next, referring to FIG. 3c, a dense layer 306 is formed on the light-emitting diode structure 305. A method of forming the dense layer 306 comprises physical vapor deposition or chemical vapor deposition. A material of the dense layer 306 comprises metal oxide, metal nitride, or GaP, wherein metal oxide comprises zinc oxide, indium oxide, tin oxide, indium tin oxide, indium zinc oxide, fluorine doped tin oxide, zinc aluminum oxide or gallium zinc oxide; wherein metal nitride comprises gallium nitride or aluminum nitride.

A film 402 is then formed on the dense layer 306. The film 402 comprises conductive nano-powders. In the present embodiment, the conductive nano-powders are formed by physical method or chemical method with targets made of indium tin oxide (ITO) sputtering target or ZnO target, wherein the physical method comprises rolling milling, vapor condensation or comminution, and the chemical method comprises vapor deposition, precipitation, hydrothermal synthesis, sol-gel method or micro-emulsion. The film 402 further comprises a binder (not shown) for binding the conductive nano-powders together. The film 402 can be formed on the dense layer 306 by coating, wherein a method of coating comprises spin-coating or blade coating. In the present embodiment, a thickness of the film 402 ranges from 10 μm to 30μm. Furthermore, the dense layer 306 is advantageous for enhancing adhesion between the film 402 and the light-emitting diode structure 305.

A step of baking the film 402 is then performed at a first temperature. After that, the step of forming the film 402 by coating and the step of baking the film 402 are repeated a predetermined number of times so as to form a thick film 403, wherein the predetermined number of times is at least 10 times or at least 20 times. Next, a pressure is applied to the thick film 403 at a second temperature, wherein the second temperature is higher than the first temperature. A thickness of the thick film 403 ranges from 100 μm to 600 μm, a transmittance of the thick film 403 ranges from 60% to 90% in the wavelength range of the light emitted from the light-emitting diode structure 305, and a resistivity of the thick film 403 ranges from 10⁻² to 10⁻⁴ Ω/cm.

A material of the nano-powders may be the same or different from a material of the dense layer 306, wherein the material of the nano-powders comprises metal oxide, metal nitride, or GaP, wherein metal oxide comprises zinc oxide, indium oxide, tin oxide, indium tin oxide, indium zinc oxide, fluorine doped tin oxide, zinc aluminum oxide or gallium zinc oxide, wherein metal nitride comprises gallium nitride or aluminum nitride. Besides, a material of the binder comprises low-temperature glass or nano silicon dioxide, wherein the low-temperature glass herein is defined as a material having a glass transition temperature ranging from 75° C. to 150° C., and the nano silicon dioxide herein is defined as silicon dioxide grains or silicon dioxide powders having a size smaller than 100 nm. Referring to FIG. 3d, a bonding layer 316 is then formed on the thick film 403.

Referring to FIG. 3e, a second substrate 311 is provided, and a light-emitting diode epitaxial structure 315 is formed on the second substrate 311 by metal-organic chemical vapor deposition (MOCVD), wherein the light-emitting diode epitaxial structure 315 comprises a first type conductive semiconductor layer (not shown), an active layer (not shown) and a second conductive type semiconductor layer (not shown) in sequence in a direction away from the second substrate 311. Referring to FIG. 3f, the thick film 403 is bonded to the light-emitting diode epitaxial structure 315 by the bonding layer 316. Referring to FIG. 3g, the second substrate 311 is then removed to expose the light-emitting diode epitaxial structure 315 by wet etching or dry etching. Referring to FIG. 3h, the carrier 310 comprising the first substrate 301 and the light-emitting diode structure 305 is removed by wet etching or dry etching. Referring to FIG. 3i to FIG. 3j, a conductive reflective layer 307 is formed on the dense layer 306, wherein the conductive reflective layer 307 is composed of metal and functions as a reflective layer and an electrode simultaneously. An electrode 308 is formed on the light-emitting diode epitaxial structure 315 and a light-emitting device 30 is formed after dicing along the scribing lines 309.

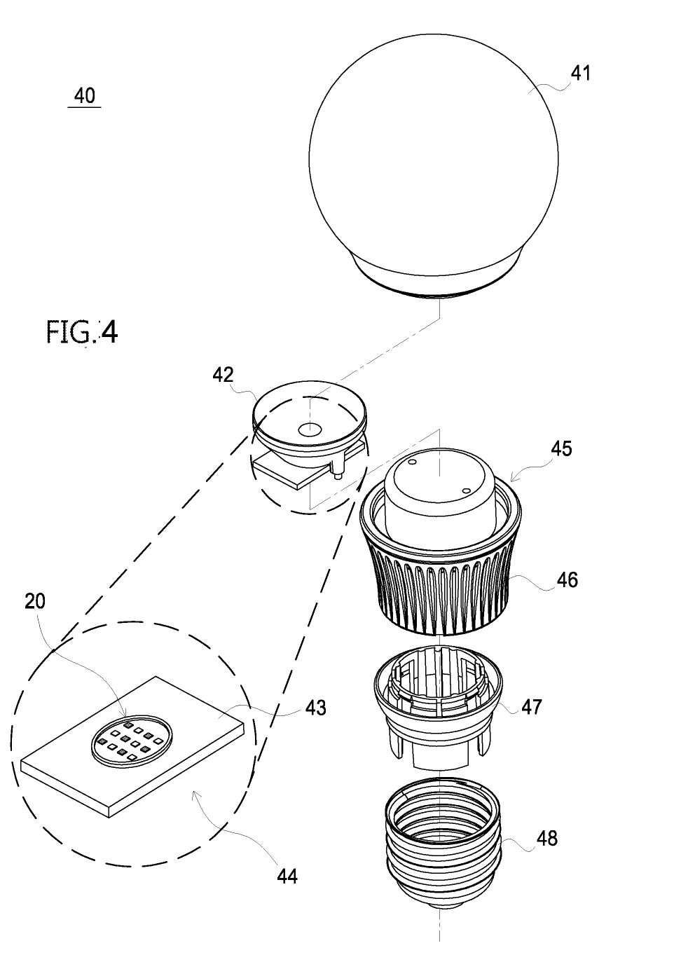

FIG. 4 is an exploded view of a light bulb 40 in accordance with another embodiment of the present application. The light bulb 40 comprises a cover 41, a lens 42 disposed in the cover 41, a lighting module 44 disposed under the lens 42, a cover holder 45, a heat sink 46, a connecting part 47, and an electrical connector 48, wherein the connecting part 47 connects the cover holder 45 to the electrical connector 48. Furthermore, the lighting module 44 comprises a carrier plate 43 and a plurality of light-emitting devices 20 and/or 30 of the embodiments as mentioned above on the carrier plate 43.

The first conductive type semiconductor layers 202, 302 and the second conductive type semiconductor layers 204, 304 as mentioned above are different in electricity, polarity or dopant, or are different in semiconductor materials used for providing electrons or holes respectively, wherein the semiconductor materials can be a single semiconductor material layer or multiple semiconductor material layers. As used herein, “multiple” is generally defined as two or more than two. The polarity can be chosen from any two of the group consisting of p-type, n-type and i-type. The active layers 203, 303, where the electrical energy and the light energy can be converted or stimulatively converted, is disposed between the first conductive type semiconductor layers 202, 302 and the second conductive type semiconductor layers 204, 304 as mentioned above. The light-emitting diode structures 205, 305 comprise a material comprising an element selected from the group consisting of: Ga, Al, In, As, P, N, Si, and the combinations thereof Preferably, the material can be AlGaInP series, III-nitride material system comprising AlGaInN series, or ZnO series. The structure of the active layer 203 can be single heterostructure (SH), double heterostructure (DH), double-side double heterostructure (DDH) or multi-quantum well (MQW) structure, wherein the wavelength of the light emitted from the active layer 203 can be changed by adjusting the number of MQW pairs.

The foregoing description of preferred and other embodiments in the present disclosure is not intended to limit or restrict the scope or applicability of the inventive concepts conceived by the Applicant. In exchange for disclosing the inventive concepts contained herein, the Applicant desires all patent rights afforded by the appended claims. Therefore, it is intended that the appended claims include all modifications and alterations to the full extent that they come within the scope of the following claims or the equivalents thereof.

What is claimed is:

1. A method for manufacturing a light-emitting device, comprising the steps of:
providing a carrier;
performing a coating step comprises coating a film on the carrier;
performing a baking step comprises baking the film at a first temperature; and
forming a thick film by repeating the coating step and the baking step a predetermined number of times.

2. The method according to claim 1, wherein the film comprises conductive powders.

3. The method according to claim 2, wherein the film comprises a binder for binding the conductive powders.

4. The method according to claim 3, wherein a material of the binder comprises low-temperature glass or nano silicon dioxide.

5. The method according to claim 2, wherein the conductive powders comprise metal oxide, metal nitride, or GaP,

6. The method according to claim 1, wherein the carrier comprises a first substrate and a light-emitting diode structure on the first substrate.

7. The method according to claim 6, further comprises a step of removing the first substrate after the thick film is formed.

8. The method according to claim 1, further comprising a step of forming a dense layer on the carrier before performing the coating step.

9. The method according to claim 8, wherein a method of forming the dense layer comprises physical vapor deposition or chemical vapor deposition.

10. The method according to claim 1, further comprising steps of:
providing a second substrate;
forming a light-emitting diode epitaxial structure on the second substrate;
forming a bonding layer on the thick film;
bonding the thick film to the light-emitting diode epitaxial structure by the bonding layer; and
removing the second substrate.

11. The method according to claim 10, further comprising a step of removing the carrier after the step of removing the second substrate.

12. The method according to claim 1, further comprising a step of applying a pressure to the thick film at a second temperature.

13. The method according to claim 12, wherein the second temperature is higher than the first temperature.

14. The method according to claim 1, further comprising a step of forming a conductive reflective layer on the thick film after the thick film is formed.

15. The method according to claim 1, wherein a method of coating comprises spin-coating or blade coating.

16. The method according to claim 1, wherein the predetermined number of times is at least 10 times.

17. The method according to claim 1, wherein the thick film comprises a transmittance ranging from 60% to 90%.

18. The method according to claim 1, wherein the thick film comprises a resistivity ranging from 10⁻² to 10⁻⁴ Ω/cm.

19. The method according to claim 1, wherein the film comprises a thickness ranging from 10 μm to 30 μm.

20. The method according to claim 1, wherein the thick film comprises a thickness ranging from 100 μm to 600 μm.
